(19) United States
(12) Patent Application Publication
(10) Pub. No.: US 2009/0215219 A1
(43) Pub. Date: Aug. 27, 2009

(54) METHOD FOR MANUFACTURING SOLAR CELL

(75) Inventors: Yoshiharu AJIKI, Fujiyoshida (JP); Hideki TANAKA, Chino (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/391,510

(22) Filed: Feb. 24, 2009

(30) Foreign Application Priority Data
Feb. 25, 2008 (JP) 2008-043150

(51) Int. Cl. H01L 51/30

(52) U.S. Cl. 438/82; 257/E51.026

(57) ABSTRACT

A method for manufacturing a solar cell having a single crystal silicon substrate and an amorphous silicon layer provided at least on one side surface of the single crystal silicon substrate is provided. The method includes the steps of: (a) forming an intrinsic amorphous silicon layer by coating a first liquid containing silicon atoms on one surface of the single crystal silicon substrate, and sintering the first liquid coated; and (b) forming an impure amorphous silicon layer on the intrinsic amorphous silicon layer.

The entire disclosure of Japanese Patent Application No. 2008-43150 filed Feb. 25, 2008 is expressly incorporated by reference herein.

### BACKGROUND

1. Technical Field

The present invention relates to solar cells, and more particularly to thin photovoltaic conversion layers of heterojunction solar cells.

2. Related Art

A HIT (Heterojunction with Intrinsic Thin-layer) solar cell is formed from a crystalline silicon substrate and a laminate of an amorphous silicon layer and a transparent conductive layer formed on one or each of two surfaces of the substrate. HIT solar cells may be characterized in that they can be manufactured by a manufacturing process in a lower temperature state, compared to crystalline silicon solar cells, and can achieve a lower manufacturing cost. For example, Japanese Laid-open Patent Application JA-P-2003-282905 (Patent Document 1) is an example of related art.

As may be seen in a variety of public documents (see for example, Tsuge, et al.: Applied Physics, 72, 7, pp. 886-889 (2003) (Non-patent Document 1) and Tanaka et al.: JJAP31 (1992) 3518 (Non-patent Document 2)), such HIT solar cells may be manufactured by the following steps. First, a doped single crystal silicon substrate having a thickness of about 200 μm is prepared, and an intrinsic amorphous silicon layer having a thickness of about 10 nm is formed on the substrate by a CVD (chemical vapor deposition) method. Then, an impure amorphous silicon layer (i.e., an amorphous silicon layer doped with impurity) having a thickness of about 10 nm is formed on the intrinsic amorphous silicon by a CVD method. The conductivity type (polarity) of the impure amorphous silicon layer is opposite to that of the single crystal silicon substrate. In other words, for example, when the single crystal silicon substrate is of a p-type, the impure amorphous silicon layer is of an n-type. Then, a conductive film (for example, an aluminum film) that is a current collector layer is formed on the back surface of the single crystal silicon substrate by a vapor deposition method or the like.

However, according to the method for manufacturing HIT solar cells described above, a vacuum processing with a CVD apparatus needs to be conducted, and therefore their manufacturing cost becomes higher. Furthermore, as a CVD method is used, a portion of the intrinsic amorphous silicon layer epitaxially grows on the single crystal silicon substrate, such that the obtained interface would contribute to deterioration of the characteristics (see, for example, Fujiwara, H et al.: APL90 (2007) 013503 (Non-patent Document 3)). Accordingly, manufacturing methods that can solve the problems described above are desired.

### SUMMARY

In accordance with an advantage of some aspects of the invention, solar cells that have excellent characteristics, and which can reduce the frequency of use of a vacuum apparatus, can be manufactured.

A manufacturing method in accordance with an embodiment of the invention pertains to a method for manufacturing a solar cell having a single crystal silicon substrate and an amorphous silicon layer provided at least on one side surface of the single crystal silicon substrate, the method including the steps of: (a) forming an intrinsic amorphous silicon layer by coating a first liquid containing silicon atoms on one surface of the single crystal silicon substrate, and sintering the coated first liquid; and (b) forming an impure amorphous silicon layer on the intrinsic amorphous silicon layer.

According to the manufacturing method of the present embodiment, a liquid process is used when forming an intrinsic amorphous silicon layer on a single crystal silicon substrate, such that the frequency of use of a vacuum apparatus can be reduced, and wastes of the material gas can also be suppressed. As a result, the process for manufacturing solar cells can be simplified, and the cost can be lowered. Also, by using a liquid process for forming an intrinsic amorphous silicon layer on a single crystal silicon substrate, the single crystal silicon substrate and the intrinsic amorphous silicon layer can have an excellent interface state, whereby solar cells with excellent characteristics can be obtained.

Preferably, a liquid process may also be used for the step (b). More specifically, the impure amorphous silicon layer may preferably be formed by coating a second liquid containing silicon atoms and dopant on the intrinsic amorphous silicon layer, and sintering the coated liquid.

As a consequence, the frequency of use of a vacuum apparatus can further be reduced.

In the manufacturing method of the present embodiment described above, for example, the conductivity type of the single crystal silicon substrate may be p-type, and the conductivity type of the impurity amorphous silicon layer may be n-type. In this case, V group elements, such as, phosphorous may be used as the dopant in the step (b).

In the manufacturing method in accordance with the present embodiment described above, for example, the conductivity type of the single crystal silicon substrate may be n-type, and the conductivity type of the impurity amorphous silicon layer may be p-type. In this case, III group elements, such as, boron may be used as the dopant in the step (b).

Each of the first liquid and the second liquid contains silane polymer. In other words, the silicon atoms described above are derived from the silane polymer. The silane polymer may be, for example, polysilane hydride. The “polysilane” is a compound that is expressed by a general formula SiₙH₂ₙ₊₂ (n<2). As a concrete example, high-order silane that may be formed through photopolymerization of cyclopentasilane (Si₅H₁₀) or the like, which has one or more annulations, by irradiating ultraviolet ray thereto, may be used. As a result, a silicon layer with excellent quality can be obtained.

The manufacturing method described above may further include forming a conductive film on the impure amorphous silicon layer.

### BRIEF DESCRIPTION OF THE DRAWINGS

FIG. 1 is a schematic cross-sectional view of the structure of a solar cell in accordance with an embodiment of the invention.

FIG. 2 is a circuit diagram showing an equivalent circuit of the solar cell.

FIG. 3 is a graph showing the relation between diode factors n and the probability of existence.

FIG. 4 is a graph showing the relation between series resistances Rs and the probability of existence.

FIG. 5 is a graph showing the relation between reverse saturation currents Io and the probability of existence.

FIG. 6 shows a result of observation showing (an image of) an interface between a single crystal silicon substrate and an intrinsic amorphous silicon layer.

FIG. 7 shows a result of observation showing (an image of) an interface between a single crystal silicon substrate and an intrinsic amorphous silicon layer.

### DESCRIPTION OF EXEMPLARY EMBODIMENTS

Preferred embodiments of the invention are described below with reference to the accompanying drawings.

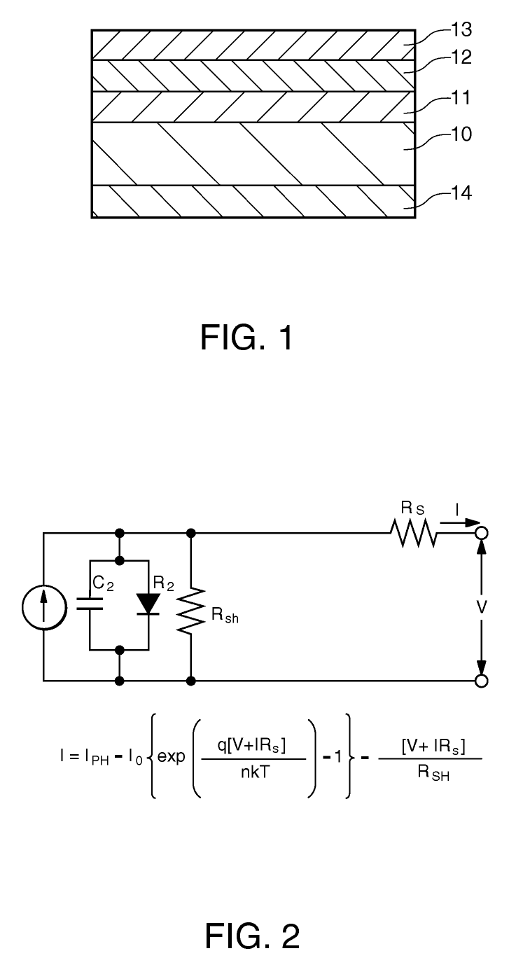

FIG. 1 is a schematic cross-sectional view showing the structure of a solar cell in accordance with an embodiment of the invention. The solar cell shown in FIG. 1 is formed from a single crystal silicon substrate 10, and an intrinsic amorphous silicon layer 11, an impure amorphous silicon layer 12 and a conductive film 13 laminated on the substrate 10. Furthermore, on the other surface of the single crystal silicon substrate 10 is provided a conductive film 14 as a current collector layer. The single crystal silicon substrate 10 may be a single crystal silicon substrate, for example, with its conductivity type being p-type, its specific resistance ρ being about 3.5 to 4.5 Ωcm², and its plate thickness being about 200 μm. In accordance with the present embodiment, at least the intrinsic amorphous silicon layer 11 is formed, using a liquid process. A method for manufacturing the solar cell in accordance with the embodiment shown in FIG. 1 is described in detail below.

First, an intrinsic amorphous silicon layer 11 is formed on one surface of a single crystal silicon substrate 10. More concretely, the intrinsic amorphous silicon layer 11 is formed through coating a liquid containing polysilane hydride on one surface of the single crystal silicon substrate 10, and sintering the coated liquid at temperatures of about 250° C. to about 350° C. for about 10 minutes to about 60 minutes. The liquid may be coated by, for example, a spin coat method. Also, the liquid may preferably be coated and sintered in an inert gas atmosphere.

It is noted that the “polysilane” is a compound that is expressed by a general formula SiₙH₂ₙ₊₂ (n<2). As a concrete example, high-order silane that is formed through photopolymerization of material which has one or more annulations, such as, cyclopentasilane (Si₅H₁₀) or the like, by irradiating ultraviolet ray thereto, may be used. The same detail also similarly applies here below.

Next, an impure amorphous silicon layer 12 is formed on the intrinsic amorphous silicon layer 11. The impure amorphous silicon layer 12 may be formed by a film forming method that includes a vacuum process, such as, a CVD method, but may preferably be formed by using a liquid process, like in the step of forming the intrinsic amorphous silicon layer 11 described above. More concretely, the impure amorphous silicon layer 12 is formed through coating a liquid containing polysilane hydride and phosphor compound as dopant on the intrinsic amorphous silicon substrate 11, and sintering the coated liquid at temperatures of about 250° C. to about 350° C. for about 10 minutes to about 60 minutes. As a result, the impure amorphous silicon layer 12 of n-type is obtained.

It is noted that, when a liquid process is not used, the impure amorphous silicon layer 12 may be formed by using, for example, a plasma CVD apparatus, under the following film forming condition.
Gas: 10 sccm of silane hydride (SiH₄), and 20 sccm of phosphor hydride (PH₃)
Substrate Temperature: 180° C.
RF power: 5 mW/cm²
Chamber inner pressure: 8-27 Pa
Film Thickness: 1 nm-20 nm (target film thickness)

Next, a conductive film 13 is formed on the impure amorphous silicon layer 12. The conductive film 13 may be a transparent conductive film, such as, for example, a film of indium tin oxide (ITO), a film of zinc oxide (ZnO) or the like. The conductive film 13 may be formed by a physical vapor phase deposition method, such as, for example, a sputter method and a vapor deposition method.

Next, a conductive film 14 is formed as a current collector layer on the other side surface of the single crystal silicon substrate 10. The conductive film 14 is, for example, a metal (AlCu) film, which is formed by a suitable method, such as, a sputter method and a vapor deposition method.

By the process described above, the solar cell in accordance with the present embodiment shown in FIG. 1 is completed. According to the present embodiment, a liquid process is used at least when an intrinsic amorphous silicon layer is formed on a single crystal silicon substrate, whereby the frequency of use of a vacuum apparatus is reduced, and wastes of the material gas can be suppressed. As a result, the process for manufacturing solar cells can be simplified, and a cost reduction can be achieved.

Also, in accordance with the present embodiment, by using a liquid process for forming an intrinsic amorphous silicon layer on a single crystal silicon substrate, an excellent interface state is formed between the single crystal silicon substrate and the intrinsic amorphous silicon layer, whereby solar cells having excellent characteristics can be obtained. The characteristics of solar cells in accordance with the present embodiment are described below with reference to comparison examples.

Solar cells manufactured according to the manufacturing condition presented in the embodiment described above, in which intrinsic amorphous silicon films 11 and impure amorphous silicon films 12 are both manufactured by the liquid process, shall be referred to as “Embodiment Example 1.” Solar cells manufactured according to the manufacturing condition presented in the embodiment described above, in which intrinsic amorphous silicon films 11 are manufactured by liquid process and impure amorphous silicon films 12 are manufactured by a plasma CVD method, shall be referred to as “Embodiment Example 2.”

On the other hand, solar cells having a structure substantially the same as the structure shown in FIG. 1, in which intrinsic amorphous silicon films are manufactured by a plasma CVD method and impure amorphous silicon films are manufactured by liquid process, are referred to as “Comparison Example 1.” Furthermore, solar cells having a structure substantially the same as the structure shown in FIG. 1, in which intrinsic amorphous silicon films and impure amorphous silicon films are both manufactured by a plasma CVD method, are referred to as “Comparison Example 2.” Manufacturing conditions for Comparison Example 1 and Comparison Example 2 are as follows.

### COMPARISON EXAMPLE 1

a. Film forming condition for forming intrinsic amorphous silicon films:
Gas: 5 sccm of silane hydride (SiH₄), and 0-100 sccm of hydrogen
Substrate Temperature: 120° C.
RF power: 25-75 mW/cm²
Chamber inner pressure: 5-27 Pa

Film Thickness: 1 nm-20 nm (target film thickness)

b. Film forming condition for forming impure amorphous silicon films:
Liquid: liquid containing polysilane hydride and phosphor compound
Sintering Temperature: 250° C.-350° C.
Sintering Time: 10 min.-60 min.

### COMPARISON EXAMPLE 2

a. Film forming condition for forming intrinsic amorphous silicon films:
Gas: 5 sccm of silane hydride (SiH₄), and 0-100 sccm of hydrogen
Substrate Temperature: 120° C.
RF power: 25-75 mW/cm²
Chamber inner pressure: 5-27 Pa
Film Thickness: 1 nm-20 nm (target film thickness)

b. Film forming condition for forming impure amorphous silicon films:
Gas: 10 sccm of silane hydride (SiH₄), and 20 sccm of phosphor hydride (PH₃)
Substrate Temperature: 180° C.
RF power: 5 mW/cm²
Chamber inner pressure: 8-27 Pa
Film Thickness: 1 nm-20 nm (target film thickness)

As for Embodiment Examples 1 and 2 and Comparison Examples 1 and 2, parameters including open-circuit voltage, short-circuit current density, shape factor and photovoltaic conversion efficiency were evaluated.

It is noted here that the open-circuit voltage (Voc) is a voltage value (V) at a current value=0 (mA/cm²), and the short-circuit current density (Jsc) is a current density (mA/cm²) at a voltage value=0 (V). Also, the shape factor (ff) is a factor that represents an internal resistance, and can be expressed by the following formula: ff=(the maximum energy Pmax that the solar cell can generate)/(Voc×Jsc). Also, the photovoltaic conversion efficiency (η) can be given by the following formula: η=Pmax/Pin=Voc×Jsc×ff/Pin

The parameters described above were evaluated. Although their detailed data is omitted, it is found that each of Embodiment Examples 1 and 2 (whose intrinsic amorphous silicon layers were formed by liquid process) had a tendency to have higher open-circuit voltage Voc and higher short-circuit current density Jsc, and lower shape factor ff, compared to each of Comparison Examples 1 and 2. Also, due to greater contribution of the shape factor ff, Comparison Examples 1 and 2 had a tendency to have higher photovoltaic conversion efficiency η.

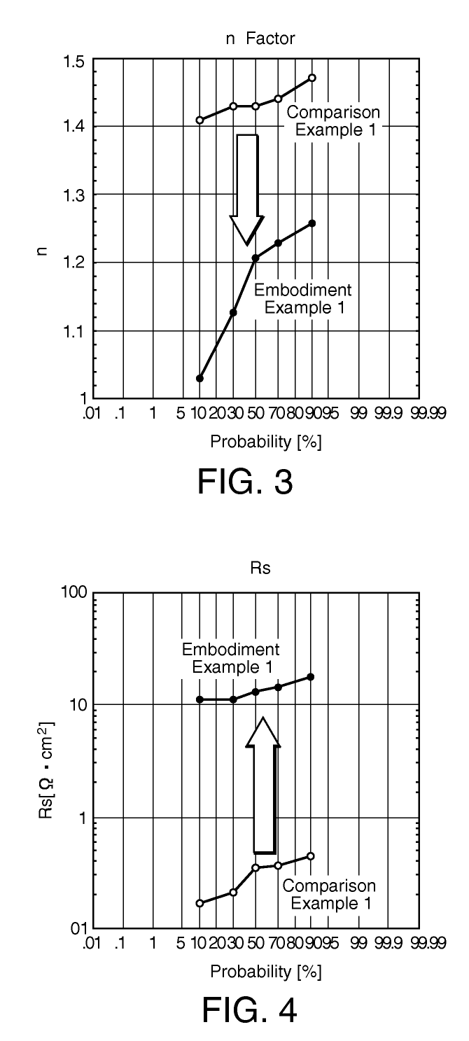

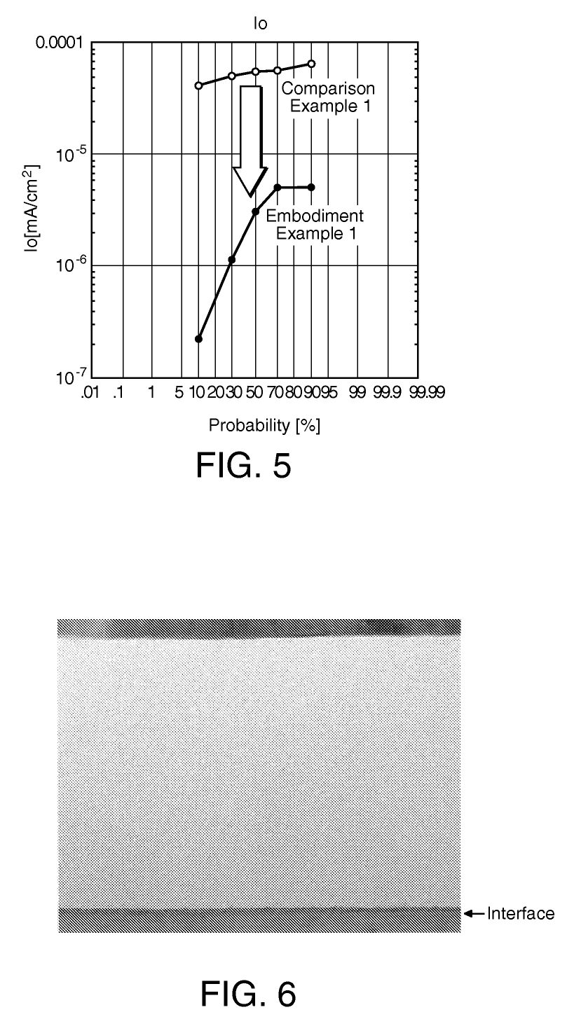

In order to understand the reason why the aforementioned tendency was obtained as a result of the characteristic evaluation, analysis using a solar cell equivalent circuit and cross-section observation by TEM (transmission electron microscopy) were conducted. The analysis using an equivalent circuit (see FIG. 2) was conducted with reference to a document entitled “Thin Solid Films 509 (2006) 123.” According to the analysis method described in the document, basically, current-voltage relational expressions are modified, and series resistance Rs, diode factor n and reverse saturation current Io of each diode are obtained from actual measurement data based on each of the expressions. Five samples were used for each of Embodiment Example 1 and Comparison Example 1 as representatives and analyzed. The analysis results are shown in FIG. 3-FIG. 5. FIG. 3 shows the relation between diode factors n and the probability of existence, FIG. 4 shows the relation between series resistances Rs and the probability of existence, and FIG. 5 shows the relation between reverse saturation currents Io and the probability of existence. It can be seen from the analysis result that Embodiment Example 1 has series resistance Rs higher by one digit than that of Comparison Example 1 (see FIG. 4). This is related to the reduction in the shape factor ff described above. Also, it is observed that the diode factor n of Embodiment Example 1 has a smaller value compared to that of Comparison Example 1, and its value is close to 1 (see FIG. 3). This result indicates that the recombination current is suppressed. This is related to the effect of increasing the short-circuit current density Jsc higher. Also, it is observed that the reverse saturation current Io of Embodiment Example 1 is smaller compared to that of Comparison Example (see FIG. 5). The results indicate that, as the recombination current can be made smaller, a high open-circuit voltage can be realized.

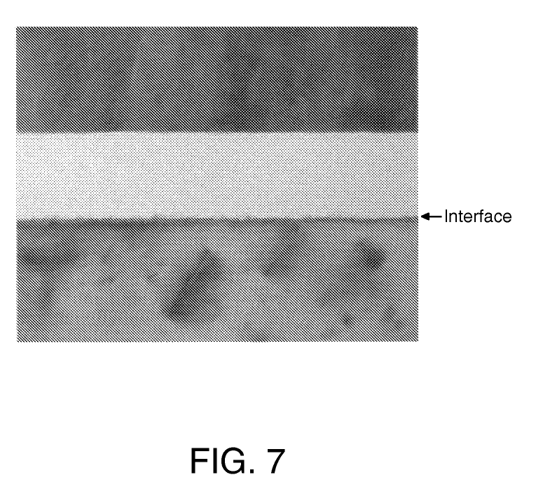

FIG. 6 and FIG. 7 are figures showing the observation results (images) of interfaces between the single crystal silicon substrate and the intrinsic amorphous silicon layer. FIG. 6 shows the observation result of the interface in Embodiment Example 1, and FIG. 7 shows the observation result of the interface in Comparison Example 1. In the sample of Embodiment Example 1 shown in FIG. 6, the film thickness of the intrinsic amorphous silicon layer was 60 nm, and the film thickness of the impure amorphous silicon layer was 30 nm. Also, in the sample of Embodiment Example 2 shown in FIG. 7, the film thickness of the intrinsic amorphous silicon layer was 10 nm, and the film thickness of the impure amorphous silicon layer was 17 nm. In Comparison Example 1, an epitaxial growth of the intrinsic amorphous silicon layer can be confirmed at the interface between the single crystal silicon substrate and the intrinsic amorphous silicon layer (FIG. 7). However, in Embodiment Example, such epitaxial growth can hardly be confirmed (FIG. 6). Accordingly, it can be assumed that the presence or absence of such epitaxial growth may contribute to recombination current and inverse saturation current.

It is noted that the invention is not limited to the details of the embodiments described above, and many modifications can be made and implemented within the scope of the subject matter of the invention. For example, in the embodiments described above, the conductivity type of the single crystal silicon substrate is p-type, and the conductivity type of the impure amorphous silicon layer is n-type. However, these conductivity types may be inversed. In other words, an intrinsic amorphous silicon layer may be provided on an n-type single crystal silicon substrate, and a p-type impure amorphous silicon layer may be provided thereon. Also, in the embodiment described above, the intrinsic amorphous silicon layer and the impure amorphous silicon layer are provided on one surface side of the single crystal silicon substrate. However, an intrinsic amorphous silicon layer and an impure amorphous silicon layer may be provided on each of the surfaces of the single crystal silicon substrate.

What is claimed is:

1. A method for manufacturing a solar cell having a single crystal silicon substrate and an amorphous silicon layer provided at least on one side surface of the single crystal silicon substrate, the method comprising the steps of:
(a) forming an intrinsic amorphous silicon layer by coating a first liquid containing silicon atoms on one surface of the single crystal silicon substrate, and sintering the first liquid coated; and
(b) forming an impure amorphous silicon layer on the intrinsic amorphous silicon layer.

2. A method for manufacturing a solar cell according to claim 1, wherein the impure amorphous silicon layer is formed by coating a second liquid containing silicon atoms and dopant on the intrinsic amorphous silicon layer, and sintering the second liquid coated.

3. A method for manufacturing a solar cell according to claim 1, wherein the conductivity type of the single crystal silicon substrate is p-type, and the conductivity type of the impurity amorphous silicon layer is n-type.

4. A method for manufacturing a solar cell according to claim 1, wherein the first liquid contains silane polymer.

5. A method for manufacturing a solar cell according to claim 2, wherein the second liquid contains silane polymer.

6. A method for manufacturing a solar cell according to claim 4, wherein the silane polymer is polysilane hydride.

7. A method for manufacturing a solar cell according to claim 1 further comprising the step of (c) forming a conductive film on the impure amorphous silicon layer.
